(19) United States
(12) Patent Application Publication
(10) Pub. No.: US 2025/0117948 A1
(43) Pub. Date: Apr. 10, 2025

(54) LEARNING-BASED DIE-TO-DIE MASK INSPECTION APPARATUS AND METHOD

(71) Applicant: Electronics and Telecommunications Research Institute, Daejeon (KR)

(72) Inventor: Hye Jin KIM, Daejeon (KR)

(21) Appl. No.: 18/907,443

(22) Filed: Oct. 4, 2024

(30) Foreign Application Priority Data
Oct. 6, 2023 (KR) 10-2023-0133578
Oct. 2, 2024 (KR) 10-2024-0133950

(51) Int. Cl. G06T 7/11; G03F 1/84; G06T 7/00

(52) U.S. Cl. CPC G06T 7/11; G03F 1/84; G06T 7/0004; G06T 2207/20081; G06T 2207/20132; G06T 2207/20224

(57) ABSTRACT

The present invention relates to a learning-based die-to-die mask inspection apparatus and method. The learning-based die-to-die mask inspection apparatus includes an image sensor that acquires images of dies of a mask, a model generation unit that generates a clean mask using a pre-trained model, and a processor that generates crop data of corresponding pairs for the same region of the dies from the images acquired by the image sensor, inputs the crop data to the model generation unit, receives the clean mask from the model generation unit, and then detects a defect in each of the dies through the crop data and the clean mask.

### CROSS-REFERENCE TO RELATED APPLICATION

This application claims priorities to and the benefits of Korean Patent Application No. 10-2023-0133578, filed on Oct. 6, 2023, and Korean Patent Application No. 10-2024-0133950, filed on Oct. 2, 2024, the disclosure of which is incorporated herein by reference in its entirety.

### BACKGROUND

### 1. Field of the Invention

The present invention relates to a learning-based die-to-die mask inspection apparatus and method.

### 2. Discussion of Related Art

Currently, transmission light mask inspection equipment using one lens conducts inspection in a die-to-die comparison method when inspecting a mask composed of two or more dies.

Inspection equipment having two lenses was mainly used as initial mask inspection equipment, but due to limitations of the maintenance of a light source, mechanical durability, a high numerical aperture (NA) conversion, an increase in lens diameter due to a decrease in wavelength, and the size of a chip that can be inspected, the frequency of use of the inspection equipment has significantly decreased and the inspection equipment is at the limit of development.

In the die-to-die mask inspection method, defects are found by obtaining an image difference using known position information of a die. A method of leaving a defect by erasing mask data through the image difference is difficult to inspect for ultra-precision defects of 1 μm or less. This is because there are vibrations of 1 μm or less due to the precision of a stage, and therefore, it is difficult to determine whether the inspection result is an error caused by vibrations, mask information, or a defect.

The background art of the present invention is disclosed in Korean Laid-Open Patent Publication No. 10-2006-0068649 (Jun. 21, 2006).

### SUMMARY OF THE INVENTION

The present invention is directed to providing a learning-based die-to-die mask inspection apparatus and method to quickly and accurately inspect for a defect in a mask by cropping a local region of a die and performing learning.

According to an aspect of the present invention, there is provided a learning-based die-to-die mask inspection apparatus including an image sensor that acquires images of dies of a mask, a model generation unit that generates a clean mask using a pre-trained model, and a processor that generates crop data of corresponding pairs for the same region of the dies from the images acquired by the image sensor, inputs the crop data to the model generation unit, receives the clean mask from the model generation unit, and then detects a defect in each of the dies through the crop data and the clean mask.

In the present invention, when ground truth (GT) is present, the model generation unit may extract a difference between the corresponding pairs using corresponding pair information, and learn so that there is no difference between a value remaining in a difference image and a value in the ground truth by applying a loss to the difference to generate the clean mask and generate the difference image.

In the present invention, the clean mask may be a gray image and an image that has intensity only in a defective portion.

In the present invention, when ground truth is not present, the model generation unit may generate the clean mask by adding the corresponding pairs so that defect information disappears.

In the present invention, the processor may generate the crop data of the corresponding pairs for the same region of the dies from the images acquired by the image sensor, transmit the crop data of the corresponding pair to the model generation unit, extract a difference image by comparing the crop data with the clean mask, and detect a defect by removing mask information from the extracted difference image.

In the present invention, the processor may detect a start position of each of the dies and extract the crop data by cropping a local region of the die according to a size of a region to be cropped based on the start position.

In the present invention, the crop data may be formed to have the same preset size and shape.

According to another aspect of the present invention, there is provided a learning-based die-to-die mask inspection method including acquiring, by an image sensor, images of dies of a mask, generating, by a processor, crop data of corresponding pairs for the same region of the dies from the images acquired by the image sensor, generating, by a model generation unit, a clean mask through the crop data using a pre-trained model, and detecting, by a processor, a defect in each of the dies through the crop data and the clean mask.

In the generating of the crop data, when ground truth (GT) is present, the model generation unit may extract a difference between the corresponding pairs using corresponding pair information, and learn so that there is no difference between a value remaining in a difference image and a value in the ground truth by applying a loss to the difference to generate the clean mask and generate the difference image.

The clean mask may be a gray image and an image that has intensity only in a defective portion.

In the generating of the crop data, when ground truth is not present, the model generation unit may generate the clean mask by adding the corresponding pairs so that defect information disappears.

In the detecting of the defect in the die, the processor may compare the crop data with the clean mask to detect a difference image, and extract a defect by removing mask information from the extracted difference image.

In the generating of the crop data, the processor may detect a start position of each of the dies and extract the crop data by cropping a local region of the die according to a size of a region to be cropped based on the start position.

The crop data may be formed to have the same preset size and shape.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a block diagram showing a configuration of a learning-based die-to-die mask inspection apparatus according to an embodiment of the present invention;

FIG. 2 is a diagram showing an example of crop data according to an embodiment of the present invention;

FIG. 3 is a diagram showing another example of the crop data according to the embodiment of the present invention;

FIG. 4 is a diagram showing still another example of the crop data according to the embodiment of the present invention; and

FIG. 5 is a flowchart of a learning-based die-to-die mask inspection method according to an embodiment of the present invention.

### DETAILED DESCRIPTION OF EXEMPLARY EMBODIMENTS

The components described in the example embodiments may be implemented by hardware components including, for example, at least one digital signal processor (DSP), a processor, a controller, an application-specific integrated circuit (ASIC), a programmable logic element, such as an FPGA, other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The method according to example embodiments may be embodied as a program that is executable by a computer, and may be implemented as various recording media such as a magnetic storage medium, an optical reading medium, and a digital storage medium.

Various techniques described herein may be implemented as digital electronic circuitry, or as computer hardware, firmware, software, or combinations thereof. The techniques may be implemented as a computer program product, i.e., a computer program tangibly embodied in an information carrier, e.g., in a machine-readable storage device (for example, a computer-readable medium) or in a propagated signal for processing by, or to control an operation of a data processing apparatus, e.g., a programmable processor, a computer, or multiple computers. A computer program(s) may be written in any form of a programming language, including compiled or interpreted languages and may be deployed in any form including a stand-alone program or a module, a component, a subroutine, or other units suitable for use in a computing environment. A computer program may be deployed to be executed on one computer or on multiple computers at one site or distributed across multiple sites and interconnected by a communication network.

Processors suitable for execution of a computer program include, by way of example, both general and special purpose microprocessors, and any one or more processors of any kind of digital computer. Generally, a processor will receive instructions and data from a read-only memory or a random access memory or both. Elements of a computer may include at least one processor to execute instructions and one or more memory devices to store instructions and data. Generally, a computer will also include or be coupled to receive data from, transfer data to, or perform both on one or more mass storage devices to store data, e.g., magnetic, magneto-optical disks, or optical disks. Examples of information carriers suitable for embodying computer program instructions and data include semiconductor memory devices, for example, magnetic media such as a hard disk, a floppy disk, and a magnetic tape, optical media such as a compact disk read only memory (CD-ROM), a digital video disk (DVD), etc. and magneto-optical media such as a floptical disk, and a read only memory (ROM), a random access memory (RAM), a flash memory, an erasable programmable ROM (EPROM), and an electrically erasable programmable ROM (EEPROM) and any other known computer readable medium. A processor and a memory may be supplemented by, or integrated into, a special purpose logic circuit.

The processor may run an operating system (OS) and one or more software applications that run on the OS. The processor device also may access, store, manipulate, process, and create data in response to execution of the software. For purpose of simplicity, the description of a processor device is used as singular; however, one skilled in the art will be appreciated that a processor device may include multiple processing elements and/or multiple types of processing elements. For example, a processor device may include multiple processors or a processor and a controller. In addition, different processing configurations are possible, such as parallel processors.

Also, non-transitory computer-readable media may be any available media that may be accessed by a computer, and may include both computer storage media and transmission media.

The present specification includes details of a number of specific implements, but it should be understood that the details do not limit any invention or what is claimable in the specification but rather describe features of the specific example embodiment. Features described in the specification in the context of individual example embodiments may be implemented as a combination in a single example embodiment. In contrast, various features described in the specification in the context of a single example embodiment may be implemented in multiple example embodiments individually or in an appropriate sub-combination. Furthermore, the features may operate in a specific combination and may be initially described as claimed in the combination, but one or more features may be excluded from the claimed combination in some cases, and the claimed combination may be changed into a sub-combination or a modification of a sub-combination.

Similarly, even though operations are described in a specific order on the drawings, it should not be understood as the operations needing to be performed in the specific order or in sequence to obtain desired results or as all the operations needing to be performed. In a specific case, multitasking and parallel processing may be advantageous. In addition, it should not be understood as requiring a separation of various apparatus components in the above described example embodiments in all example embodiments, and it should be understood that the above-described program components and apparatuses may be incorporated into a single software product or may be packaged in multiple software products.

It should be understood that the example embodiments disclosed herein are merely illustrative and are not intended to limit the scope of the invention. It will be apparent to one of ordinary skill in the art that various modifications of the example embodiments may be made without departing from the spirit and scope of the claims and their equivalents.

Hereinafter, with reference to the accompanying drawings, embodiments of the present disclosure will be described in detail so that a person skilled in the art can readily carry out the present disclosure. However, the present disclosure may be embodied in many different forms and is not limited to the embodiments described herein.

In the following description of the embodiments of the present disclosure, a detailed description of known functions and configurations incorporated herein will be omitted when it may make the subject matter of the present disclosure rather unclear. Parts not related to the description of the present disclosure in the drawings are omitted, and like parts are denoted by similar reference numerals.

In the present disclosure, components that are distinguished from each other are intended to clearly illustrate each feature. However, it does not necessarily mean that the components are separate. That is, a plurality of components may be integrated into one hardware or software unit, or a single component may be distributed into a plurality of hardware or software units. Thus, unless otherwise noted, such integrated or distributed embodiments are also included within the scope of the present disclosure.

In the present disclosure, components described in the various embodiments are not necessarily essential components, and some may be optional components. Accordingly, embodiments consisting of a subset of the components described in one embodiment are also included within the scope of the present disclosure. In addition, embodiments that include other components in addition to the components described in the various embodiments are also included in the scope of the present disclosure.

Hereinafter, with reference to the accompanying drawings, embodiments of the present disclosure will be described in detail so that a person skilled in the art can readily carry out the present disclosure. However, the present disclosure may be embodied in many different forms and is not limited to the embodiments described herein.

In the following description of the embodiments of the present disclosure, a detailed description of known functions and configurations incorporated herein will be omitted when it may make the subject matter of the present disclosure rather unclear. Parts not related to the description of the present disclosure in the drawings are omitted, and like parts are denoted by similar reference numerals.

In the present disclosure, when a component is referred to as being “linked,” “coupled,” or “connected” to another component, it is understood that not only a direct connection relationship but also an indirect connection relationship through an intermediate component may also be included. In addition, when a component is referred to as “comprising” or “having” another component, it may mean further inclusion of another component not the exclusion thereof, unless explicitly described to the contrary.

In the present disclosure, the terms first, second, etc. are used only for the purpose of distinguishing one component from another, and do not limit the order or importance of components, etc., unless specifically stated otherwise. Thus, within the scope of this disclosure, a first component in one exemplary embodiment may be referred to as a second component in another embodiment, and similarly a second component in one exemplary embodiment may be referred to as a first component.

In the present disclosure, components that are distinguished from each other are intended to clearly illustrate each feature. However, it does not necessarily mean that the components are separate. That is, a plurality of components may be integrated into one hardware or software unit, or a single component may be distributed into a plurality of hardware or software units. Thus, unless otherwise noted, such integrated or distributed embodiments are also included within the scope of the present disclosure.

In the present disclosure, components described in the various embodiments are not necessarily essential components, and some may be optional components. Accordingly, embodiments consisting of a subset of the components described in one embodiment are also included within the scope of the present disclosure. In addition, exemplary embodiments that include other components in addition to the components described in the various embodiments are also included in the scope of the present disclosure.

Hereinafter, embodiments of a learning-based die-to-die mask inspection apparatus and method according to the present invention will be described. In this process, the thicknesses of the lines and the sizes of the components shown in the accompanying drawings may be exaggerated for the sake of clarity and convenience of description. In addition, the terms described below are terms defined in consideration of their functions in the present invention, and may vary depending on the intention or custom of the user or operator. Therefore, the definitions of these terms should be made based on the contents throughout this specification.

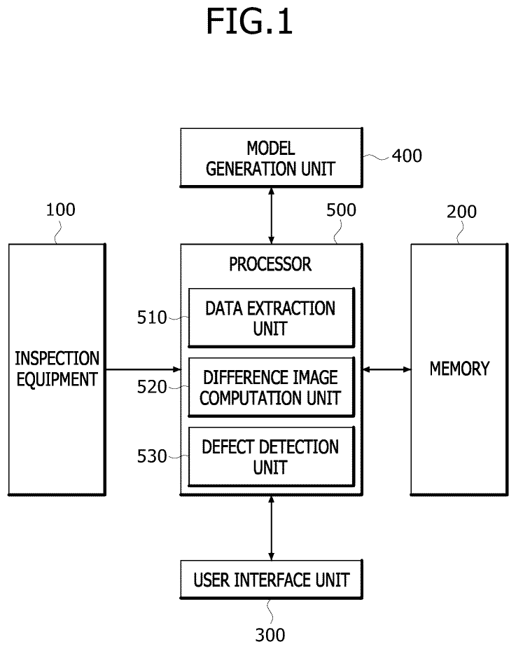

FIG. 1 is a block diagram showing a configuration of a learning-based die-to-die mask inspection apparatus according to an embodiment of the present invention.

Referring to FIG. 1, the learning-based die-to-die mask inspection apparatus according to the embodiment of the present invention may include an image sensor 100, a memory 200, a user interface unit 300, a model generation unit 400, and a processor 500.

In this embodiment, a mask 700 is an extreme ultraviolet (EUV)/deep ultraviolet (DUV) mask and may have a plurality of dies 600 on which mask patterns of the same shape are formed.

The image sensor 100 may generate an image obtained by scanning the dies 600 formed on the mask 700.

The image sensor 100 may be a charge-coupled device (CCD) camera that is installed above the die 600 and scans the mask 700. A type of the image sensor 100 is not particularly limited.

The memory 200 may store various types of data used by the processor 500. The memory 200 may store instructions to perform operations or steps according to an embodiment of the present invention. That is, the memory 200 may store instructions to quickly and accurately inspect the mask 700 by cropping a local region of the die 600 and performing learning.

The memory 200 may include at least one storage medium among a flash memory type medium, a hard disk type medium, a multimedia card micro type medium, a card type memory, a random access memory (RAM), a static random access memory (SRAM), a read-only memory (ROM), a programmable read-only memory PROM), an erasable programmable read-only memory (EPROM), and an electrically erasable programmable read-only memory (EEPROM).

The user interface unit 300 may provide a user interface.

The user interface unit 300 may receive various control instructions for mask inspection from a user.

The user interface unit 300 may output images and data processed and generated during a mask inspection process.

The images and data may include, but are not particularly limited to, the image scanned by the image sensor 100, crop data, clean masks, difference images, and defect inspection results. The images, crop data, clean masks, difference images, and defect inspection results will be described below.

As the user interface unit 300, for example, a user interface such as a keyboard, a mouse, a touchpad, a touchscreen, an electronic pen, a touch button, or the like may be provided. The user interface unit 300 may also include a printer, display, etc., to output data. Here, the display may be implemented as, for example, a thin film transistor-liquid crystal display (TFT-LCD) panel, a light emitting diode (LED) panel, an organic LED (OLED) panel, an active matrix OLED (AMOLED) panel, a flexible panel, etc.

The model generation unit 400 may receive paired crop data for each die 600 for the same region of each of the dies 600 from the processor 500. Here, the model generation unit 400 may be implemented in the form of a separate processor, device, or module that learns corresponding pair information of the crop data to generate clean data.

The crop data may include a corresponding pair of crop images cropped for the same region of the dies 600.

The model generation unit 400 may generate a model by utilizing corresponding pair information of crop data 610 received from the processor 500 and performing learning.

The model generation unit 400 may generate crop data from the crop data 610 using a pre-trained model.

That is, when ground truth (GT) is present, the model generation unit 400 may extract a difference between corresponding pairs using the corresponding pair information. The model generation unit 400 may learn so that there is no difference between a value remaining in a difference image and a value in the ground truth by applying a loss to the difference.

When learning is performed in this way, a resulting image that optimizes the loss may be a clean image in which the stage shaking part of the difference image disappears except for the defective portion. Such a clean image may be for a clean mask. The model generation unit 400 may already generate the clean mask and generate the difference image in the above-described process.

After learning is completed, the model generation unit 400 may generate the clean mask for an input image. The clean mask is a gray image in which only the defective portion has intensity and which allows a defect to be easily detected.

In another embodiment, when the GT is not present and the number of corresponding pairs increases, the model generation unit 400 may subtract actual mask patterns according to the difference between the corresponding pairs. In this case, only the defect information remains.

In addition, the model generation unit 400 adds many corresponding pairs to leave only strong pattern information, and defect information in the image gradually disappears. Such an image may become a clean mask.

That is, the model generation unit 400 may remove the defect based on learning in a situation where the GT is not present.

The processor 500 may be connected to the memory 200 and execute instructions stored in the memory 200. The processor 500 may execute instructions stored in the memory 200 to control at least one other component (e.g., a hardware or software component) connected to the processor 500 and perform data processing or operations on various types of data.

In addition, the processor 500 may be configured to perform each function separately at the hardware, software, or logic level. In this case, dedicated hardware may be used to perform each function. To this end, the processor 500 may be implemented as at least one of an application specific integrated circuit (ASIC), a digital signal processor (DSP), a programmable logic device (PLD), a field programmable gate array (FPGA), a central processing unit (CPU), a microcontroller, and/or a microprocessor, or may include at least one of these components.

The processor 500 may be implemented as a CPU or a System on Chip (SoC), run an operating system or application to control a plurality of hardware or software components connected to the processor 500, and perform data processing and operations on various types of data. The processor 500 may be configured to execute at least one instruction stored in the memory 200 and store data resulting from the execution in the memory 200.

The processor 500 may receive crop data 610 from the image sensor 100.

Generally, in the case of a semiconductor, since a high-magnification optical system is used to find a micro-scale defect, a single image may 1 GB or more in size. This size is impossible to learn with the currently existing GPU memory. Therefore, large data is cropped into smaller pieces of data.

For example, when the number of dies 600 is 3, the entirety of each die 600 is not used, and information about one die 600 may not be included in one image. That is, one die 600 may be composed of several to hundreds of images.

Therefore, the crop data 610 is brought from the die 600, and in this case, the corresponding pairs may be brought in various shapes and sizes.

Since the image is difficult to recognize by resolution thereof, different sizes and shapes of cropped data 610 are needed. That is, a crop shape is needed to better secure patterns such as large crop data 610, small crop data 610, vertically long crop data, and horizontally long crop data. In this case, as long as the corresponding pair information of the die 600 can be maintained, the size or shape of crop data is not limited.

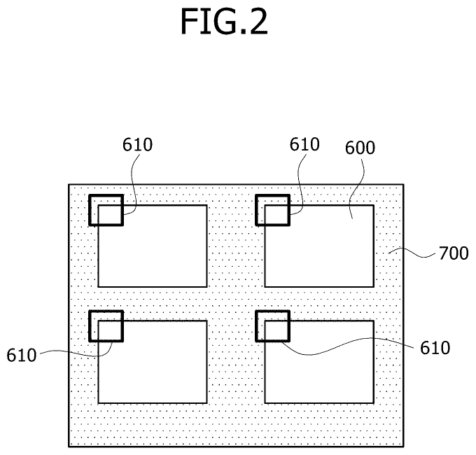

Crop data of the corresponding pairs for the same region may be formed in various sizes, orientations, and shapes. This is as shown in FIGS. 2 to 4.

FIGS. 2 to 4 are diagrams showing examples of crop data according to an embodiment of the present invention.

FIG. 2 shows the crop data 610 cropped into a square shape.

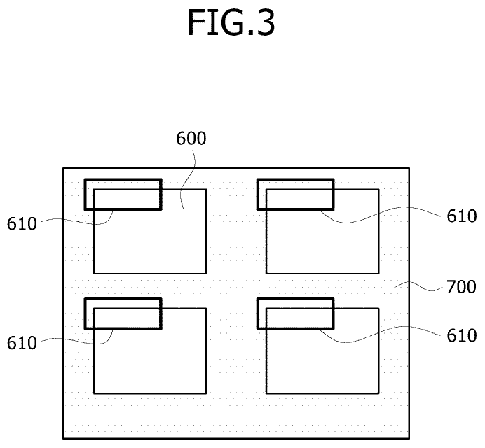

FIG. 3 shows the crop data 610 cropped into a horizontally long rectangular shape.

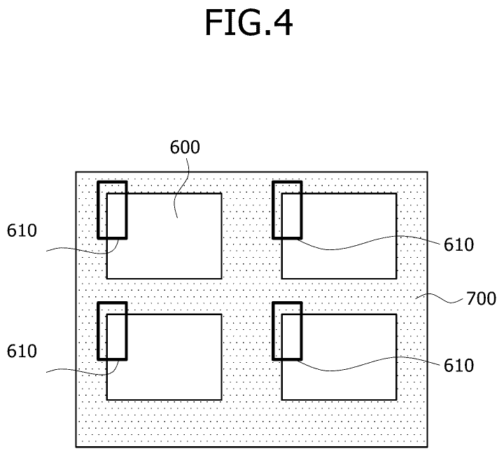

FIG. 4 shows the crop data 610 cropped into a vertically long rectangular shape.

The processor 500 may transmit the crop data 610 to the model generation unit 400 and receive a clean mask from the model generation unit 400.

The processor 500 may extract a difference image between the clean image and the clean mask received from the model generation unit 400.

The processor 500 may detect the defect remaining after mask information is removed from the extracted difference image.

The processor 500 may include a data extraction unit 510, a difference image computation unit 520, and a defect detection unit 530.

The data extraction unit 510 may extract paired crop data for each die for the same region of the die 600 from the image received from the image sensor 100.

A semiconductor may include multiple dies 600 in one mask 700. In this case, when generating a mask pattern on the semiconductor, a start position of the die 600 may be detected. Therefore, the data extraction unit 510 may obtain the start position of the die 600 as a Y coordinate from the mask pattern and scan the die 600 vertically to obtain an X coordinate.

The data extraction unit 510 may detect whether the scanned region is the same region based on the extracted X coordinate and Y coordinate.

The data extraction unit 510 may extract crop data by cropping a local region of the die according to the size (height and width) of a region to be cropped based on the extracted X and Y coordinates.

The data extraction unit 510 resizes the crop data 610 to the same size so that a narrow region may be viewed in a larger size or information on a wide region may be viewed on the image.

In this case, the data extraction unit 510 extracts crop data in a preset size, orientation, and shape, and may form the crop data to have the same preset size and shape.

The difference image computation unit 520 may receive crop data 610 from the data extraction unit 510 and receive the clean mask generated by the model generation unit 400.

The difference image computation unit 520 may detect a difference image by comparing the crop data 610 and the clean mask.

The defect detection unit 530 may detect the defect in the difference image computed by the difference image computation unit 520. Here, since the difference image is a gray image and a brightly colored portion corresponds to the defect, the defect detection unit 530 removes mask information from the difference image and detects the defect corresponding to the brightly colored portion.

In this embodiment, in order to help understanding of this embodiment, the data extraction unit 510, the difference image computation unit 520, and the defect detection unit 530 are described as separate components within the processor 500, but depending on an embodiment, the processor 500 may be implemented as a configuration in which each sub-component is performed in an integrated manner.

While the embodiment describes the use of the difference image of the crop data and the clean mask for the mask inspection as an example, the technical scope of the present invention is not limited to this, and may also include detecting defects in a die using a corresponding pair of crop data and clean mask.

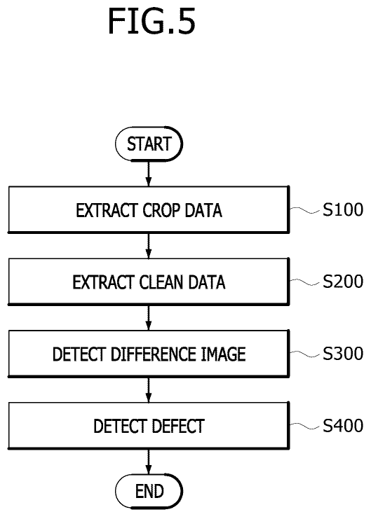

Hereinafter, a learning-based die-to-die mask inspection method according to an embodiment of the present invention will be described with reference to FIG. 5.

FIG. 5 is a flowchart of the learning-based die-to-die mask inspection method according to an embodiment of the present invention.

Referring to FIG. 5, the image sensor 100 may scan the mask 700 loaded onto the stage to generate an image obtained by scanning the die 600 formed on the mask 700.

The image sensor 100 may input the generated image to the processor 500. The processor 500 may receive the crop data 610 from the image sensor 100.

The data extraction unit 510 may extract paired crop data for each die for the same region of the die 600 from the image received from the image sensor 100 (S200).

In this case, the data extraction unit 510 may extract crop data by cropping a local region of the die according to the size (height and width) of a region to be cropped based on the X and Y coordinates.

In addition, the data extraction unit 510 may form crop data of the corresponding pair for the same region in various sizes, orientations, and shapes.

The model generation unit 400 may receive the crop data 610 from the data extraction unit 510.

The model generation unit 400 may generate a clean mask by utilizing corresponding pair information of the crop data 610 received from the processor 500 and performing learning. That is, the model generation unit 400 may generate the clean mask by utilizing the corresponding pair information of the crop data 610 using the trained model.

Subsequently, the difference image computation unit 520 may receive the crop data 610 from the data extraction unit 510 and receive the clean mask from the model generation unit 400.

The difference image computation unit 520 may detect a difference image by comparing the crop data 610 with the clean mask (S300).

Finally, the defect detection unit 530 may remove the mask information from the difference image and detect the defect corresponding to the brightly colored portion (S400).

In this way, the learning-based die-to-die mask inspection apparatus and method according to an embodiment of the present invention can inspect the mask quickly and accurately by cropping a local region of the die and precisely inspecting the local region of the die through learning.

A learning-based die-to-die mask inspection apparatus and method according to another aspect of the present invention can remove such residual marks by adding or subtracting repeated information of the different cropped images for the same pattern to or from the shaking of a stage, thereby minimizing noise inspection performance limitations caused by the shaking of the stage that can occur during current semiconductor inspection.

A learning-based die-to-die mask inspection apparatus and method according to still another aspect of the present invention are economically very effective because the apparatus and method do not need to purchase an expensive stage in order for eliminating the shaking of a stage, and can detect defects more precisely.

Although the present invention has been described with reference to embodiments illustrated in the drawings, these are merely exemplary, and those skilled in the art will understand that various modifications and equivalent other embodiments are possible therefrom. Therefore, the technical protection scope of the present invention should be defined by the following patent claims.

What is claimed is:

1. A learning-based die-to-die mask inspection apparatus comprising:
an image sensor that acquires images of dies of a mask;
a model generation unit that generates a clean mask using a pre-trained model; and
a processor that generates crop data of corresponding pairs for the same region of the dies from the images acquired by the image sensor, inputs the crop data to the model generation unit, receives the clean mask from the model generation unit, and then detects a defect in each of the dies through the crop data and the clean mask.

2. The apparatus of claim 1, wherein, when ground truth (GT) is present, the model generation unit extracts a difference between the corresponding pairs using corresponding pair information, and learns so that there is no difference between a value remaining in a difference image and a value in the ground truth by applying a loss to the difference to generate the clean mask and generate the difference image.

3. The apparatus of claim 2, wherein the clean mask is a gray image and an image that has intensity only in a defective portion.

4. The apparatus of claim 1, wherein, when ground truth (GT) is not present, the model generation unit generates the clean mask by adding the corresponding pairs so that defect information disappears.

5. The apparatus of claim 1, wherein the processor generates the crop data of the corresponding pairs for the same region of the dies from the images acquired by the image sensor, transmits the crop data of the corresponding pair to the model generation unit, extracts a difference image by comparing the crop data with the clean mask, and detects a defect by removing mask information from the extracted difference image.

6. The apparatus of claim 5, wherein the processor detects a start position of each of the dies and extracts the crop data by cropping a local region of the die according to a size of a region to be cropped based on the start position.

7. The apparatus of claim 6, wherein the crop data is formed to have the same preset size and shape.

8. A learning-based die-to-die mask inspection method comprising:
acquiring, by an image sensor, images of dies of a mask;
generating, by a processor, crop data of corresponding pairs for the same region of the dies from the images acquired by the image sensor;
generating, by a model generation unit, a clean mask through the crop data using a pre-trained model; and
detecting, by the processor, a defect in each of the dies through the crop data and the clean mask.

9. The method of claim 8, wherein, in the generating of the crop data, when ground truth (GT) is present, the model generation unit extracts a difference between the corresponding pairs using corresponding pair information, and learns so that there is no difference between a value remaining in a difference image and a value in the ground truth by applying a loss to the difference to generate the clean mask and generate the difference image.

10. The method of claim 8, wherein the clean mask is a gray image and an image that has intensity only in a defective portion.

11. The method of claim 8, wherein, in the generating of the crop data, when ground truth (GT) is not present, the model generation unit generates the clean mask by adding the corresponding pairs so that defect information disappears.

12. The method of claim 8, wherein, in the detecting of the defect in the die, the processor compares the crop data with the clean mask to extract a difference image, and detects a defect by removing mask information from the extracted difference image.

13. The method of claim 8, wherein, in the generating of the crop data, the processor detects a start position of each of the dies and extracts the crop data by cropping a local region of the die according to a size of a region to be cropped based on the start position.

14. The method of claim 13, wherein the crop data is formed to have the same preset size and shape.
